(19) United States
(12) Patent Application Publication
(10) Pub. No.: US 2002/0142550 A1
(43) Pub. Date: Oct. 3, 2002

(54) Semiconductor device and method of manufacturing the same

(76) Inventor: Keita Kumamoto, Tokyo (JP)

Correspondence Address: Darryl G. Walker, WALKER & SAKO, LLP, Suite 235, 300 South First Street, San Jose, CA, 95113, US

(21) Appl. No.: 10/106,771

(22) Filed: Mar. 26, 2002

(30) Foreign Application Priority Data
Mar. 28, 2001 (JP) 2001-093055

(51) Int. Cl. H01L 21/336; H01L 21/76

(52) U.S. Cl. 438/296; 438/435; 438/437

(57) ABSTRACT

A semiconductor device including an insulating film (6) embedded in a concave portion is disclosed. A nitride film liner (3) may be formed inside a concave portion formed in a semiconductor substrate (1). An anti-static insulating film (10) may be formed on nitride film liner (3) by a thermal chemical vapor deposition (CVD) method. Embedded insulating film (6) may be formed on the anti-static insulating film (10) by a high-density plasma CVD method so as to essentially fill the concave portion. In this way, peeling off of insulating film (6) may be reduced and a formation of a groove in a trench isolation structure may be suppressed.

### TECHNICAL FIELD

The present invention relates generally to a semiconductor device and method of manufacturing the same and more particularly to a semiconductor device that may have an insulating film embedded in a concave portion formed in a semiconductor substrate and a method of forming the same.

### BACKGROUND OF THE INVENTION

It is a continuing goal to increase the integration level of semiconductor devices. In order to do so, it is desirable to make device structures and device isolation structures smaller. One method of providing smaller device isolation structures is to use a trench isolation structure in place of a conventional local oxidation of silicon (LOCOS) method.

A conventional trench isolation method will now be described with reference to FIGS. 5 to 7. The conventional trench isolation method includes forming a concave portion or trench inside a semiconductor substrate. The trench is etched in a silicon substrate to a depth required for isolation between adjacent devices, forming an insulating film to fill the trench, and then removing the insulating film located outside the trench with a flattening step.

FIGS. 5 and 6 are cross-sectional diagrams of a conventional trench isolation structure after various process steps.

Referring now to FIG. 5(a), a silicon oxide film 102 and a silicon nitride film 103 are formed sequentially on a silicon substrate 101. Next, a resist pattern (not shown) is formed and etched to expose silicon nitride film 103 located over a region (non-active region) where a trench is to be formed. Then, using the resist pattern as a mask, silicon nitride film 103 and silicon oxide film 102 are etched sequentially until the surface of silicon substrate 101 is exposed. The resist pattern is then removed, the exposed silicon substrate 101 is etched using silicon nitride film 103 as a mask to form a trench T.

Referring now to FIG. 5(b), a thermal oxide film 104 is formed on the inner wall surface of trench T. Thermal oxide film 104 helps to compensate for damage to the surface of the substrate 101 caused the above-mentioned etching carried out to form trench T. Thermal oxide film 104 also helps to prevent dislocation from occurring inside the substrate 101 by rounding off the corners of trench T to relieve stress.

Referring now to FIG. 5(c), a nitride film liner 105 is then formed over the surface and an embedding insulating film 106 is then formed on the surface to fill trench T. Nitride film liner 105 is formed to prevent oxygen from infiltrating inside the wall of trench T through embedding insulating film 106 in a subsequent oxidation step, or the like. In this way, the trench walls may be prevented from being further oxidized. If oxygen infiltrates the wall of trench T, silicon in that portion is oxidized and increases in volume to produce stress that can cause defects such as dislocation, or the like, which can cause device characteristics to deteriorate.

Referring now to FIG. 6(a), chemical mechanical polishing (CMP) is carried out until silicon nitride film 103 is exposed to flatten the surface of the substrate.

Referring now to FIG. 6(b), silicon nitride film 103 formed over the region (active region) other than the non-active region of the substrate 101 is removed by wet etching. At this time, if the thickness of nitride film liner 105 is thick, nitride film liner 105 is etched deep inside the trench. As will be illustrated later, this causes a groove to be formed in this region in a subsequent step.

Referring now to FIG. 6(c), silicon oxide film 102 over the active region and a protruding portion of embedding insulating film 106 in the non-active region are removed in a wet washing step (wet etching) to form a target trench isolation structure. At this time, a groove D is formed along the edge of the device isolation region (trench isolation region) formed with the insulating film embedded in the trench. Groove D is caused due to a part of nitride film liner 105 being etched inside the trench (illustrated in FIG. 6(b)). When groove D is wide, an electrically conductive material tends to remain inside groove D in a later step of forming gate electrode. This can cause short circuit failure in these gate electrodes. Also, the electric field of the gate electrodes can be increased in the substrate comers defined by groove D. Such an increased electric field causes instability in device characteristics, such as threshold voltage, which causes undesirable effects such as an increase of leakage currents, or the like. In order to suppress the formation of groove D, it is desirable that nitride film liner 105 has a relatively thin film thickness.

On the other hand, due to the necessity of making a device isolation region smaller, the method of embedding an insulating film inside a smaller trench becomes more important. Conventionally, various CVD (chemical vapor deposition) methods have been used to deposit an insulating film. In particular, a plasma CVD method is used for the formation of an interlayer insulating film for multi-layer wiring. For example, a high-density plasma CVD method used for the formation of an interlayer insulating film for minute multi-layer wiring provides dense film quality and high embeddability with respect to a narrow concave portion pattern. Hence, the use of an insulating film deposited by a plasma CVD method as an insulting film embedded inside a trench may allow a minute trench isolation region to be formed.

However, direct formation of a plasma CVD film on thin nitride film 105 cause problem that the embedding insulating film may be partially peeled off.

FIGS. 7(a) and 7(b) show a peeled-off state of an embedding insulating film. FIG. 7(a) is an optical microphotograph of a substrate planed directly after a deposition of a high-density plasma CVD oxide film inside a trench with a nitride film liner formed therein. Whitish spots in FIG. 7(a) indicate peeled-off portions.

FIG. 7(b) is an enlarged cross-sectional SEM photograph of a part of FIG. 7(a). FIG. 7(b) illustrates lift of the nitride film due to peeling off. The peeling off of the film may be frequently caused in a portion with a relatively wide area.

It is presumed that such peeling off is caused by an influence of charged particles, such as plasma produced during deposition or the like, upon the nitride film liner as a base or the interface between the nitride film liner and the substrate. In the above-mentioned example, in addition to the plasma produced in high-density plasma CVD process trapped by the interface between the nitride film liner and the substrate, weak film strength the nitride film liner with film thickness on the order of several nanometers has, result in the peeling off as illustrated in FIG. 7.

Japanese Patent Application Laid-Open No. Hei 11-121621 (JPA '621) describes a technique for preventing the lift of a nitride film. The nitride film illustrated in JPA '621 is not directed to trench isolation but is directed to a nitride film formed as an etching stopper film for contact formation. JPA '621 shows a plasma oxide film formed on the nitride film as an interlayer film before the formation of a wiring layer. In JPA '621, a method is employed in which a plasma process is carried out before the formation of the etching stopper film. This process lead to the formation of nitride film with sufficient thickness on silicon oxide. Thus, the film strength of the nitride film is sufficient and lift of the nitride film is prevented. However, in a trench isolation, the formation of a thick nitride film liner cause a wide groove D which is enlarged by deep protrusion inside a trench of wet etching along the nitride film liner. As discussed earlier, this can cause defects, such as a short circuit in gate electrodes or the like, and deterioration in device characteristics.

In view of the above discussion, it would be desirable to provide a semiconductor device including an insulating film embedded structure such that the insulating film may be embedded without causing peeling off in a concave portion that may have a thin nitride film formed therein. It would also be desirable to provide a method of manufacturing such a semiconductor device.

### SUMMARY OF THE INVENTION

According to the present embodiments, a semiconductor device including an insulating film embedded in a concave portion has been disclosed. A nitride film liner may be formed inside a concave portion formed in a semiconductor substrate. An anti-static insulating film may be formed on nitride film liner by a thermal chemical vapor deposition (CVD) method. An embedded insulating film may be formed on the anti-static insulating film by a high-density plasma CVD method so as to essentially fill a concave portion. In this way, peeling off of an insulating film may be reduced and a formation of a groove in a trench isolation structure may be suppressed.

According to one aspect of the embodiments, a semiconductor device may include a plurality of first concave portions formed on a semiconductor substrate. Each concave portion may include an oxidation resistant insulating film formed thereon. An anti-static insulating film may be formed on the oxidation resistant insulating film. An embedding insulating film may be formed inside each of the concave portions to essentially fill each of the concave portions.

According to another aspect of the embodiments, each concave portion may be a trench isolation region including a first insulating film formed on trench walls.

According to another aspect of the embodiments, each concave portion may be essentially defined by adjacent gate electrodes.

According to another aspect of the embodiments, formation of the anti-static insulating film may include thermal chemical vapor deposition (CVD).

According to another aspect of the embodiments, formation of the anti-static insulating film may include plasma CVD.

According to another aspect of the embodiments, formation of the anti-static insulating film may include high-density plasma CVD.

According to another aspect of the embodiments, the oxidation-resistant insulating film may include a nitride film with a thickness of about 4 nm to 20 nm.

According to another aspect of the embodiments, the anti-static insulating film may include an oxide film with a thickness of about 5 nm to 30 nm.

According to another aspect of the embodiments, a method of manufacturing a semiconductor device may include the steps of forming an oxidation-resistant insulating film on a surface including a concave portion formed on a semiconductor substrate, forming an anti-static insulating film on the oxidation-resistant insulating film, and forming an embedding insulating film on the anti-static insulating film to essentially fill the concave portion. The formation of the embedding insulating film may include plasma chemical vapor deposition (CVD).

According to another aspect of the embodiments, the concave portion may be essentially defined by adjacent gate electrodes.

According to another aspect of the embodiments, forming the embedding insulating film may include high-density plasma chemical vapor deposition (CVD).

According to another aspect of the embodiments, the oxidation-resistant insulating film may include a nitride film having a thickness of about 4 nm to 20 nm.

According to another aspect of the embodiments, forming the anti-static insulating film may include a thermal CVD method.

According to another aspect of the embodiments, the anti-static insulating film may include an oxide film having a thickness of about 5 nm to 30 nm.

According to another aspect of the embodiments, a method of manufacturing a semiconductor device may include the steps of forming a mask layer including a first oxidation-resistant insulating film on a semiconductor substrate, forming a predetermined opening pattern in the mask layer, forming a trench by etching an exposed portion of the semiconductor substrate with the mask layer used as a mask, forming a first insulating film on an inner wall of the trench, forming a second oxidation-resistant insulating film on the first insulating film, forming an anti-static insulting film on the second oxidation-resistant insulating film, forming a second insulating film on the ant-static insulating film by a plasma chemical vapor deposition (CVD) method to essentially fill the trench, carrying out a flattening treatment so that the mask layer is exposed, and removing the mask layer by wet etching. In this way, a trench isolation structure may be formed including the second insulating film, the first insulating film, the second oxidation-resistant film, and the anti-static insulating film.

According to another aspect of the embodiments, forming the second insulating film may include high-density plasma CVD.

According to another aspect of the embodiments, the second oxidation-resistant insulating film may include a nitride film having a thickness of about 4 nm to 20 nm.

According to another aspect of the embodiments, the second oxidation-resistant insulating film may include a nitride film having a thickness of about 5 nm to 7 nm.

According to another aspect of the embodiments, forming the anti-static insulating film may include a thermal CVD method.

According to another aspect of the embodiments, the anti-static insulating film may include an oxide film having a thickness of about 5 nm to 30 nm.

### BRIEF DESCRIPTION OF THE DRAWINGS

FIGS. 1(a)-(c) are cross sectional views of a semiconductor device according to an embodiment after various processing steps.

FIGS. 2(a)-(c) are cross sectional views of a semiconductor device according to an embodiment after various processing steps.

FIGS. 3(a)-(c) are cross sectional views of a semiconductor device according to an embodiment after various processing steps.

FIGS. 4(a)-(c) are cross sectional views of a semiconductor device according to an embodiment after various processing steps.

FIGS. 5(a)-(c) are cross-sectional diagrams of a conventional trench isolation structure after various process steps.

FIGS. 6(a)-(c) are cross-sectional diagrams of a conventional trench isolation structure after various process steps.

FIG. 7(a) is an optical microphotograph of a substrate planed directly after a deposition of a high-density plasma CVD oxide film inside a trench with a nitride film liner formed therein.

FIG. 7(b) is an enlarged cross-sectional SEM photograph of a part of FIG. 7(a).

### DETAILED DESCRIPTION OF THE EMBODIMENTS

Various embodiments of the present invention will now be described in detail with reference to a number of drawings.

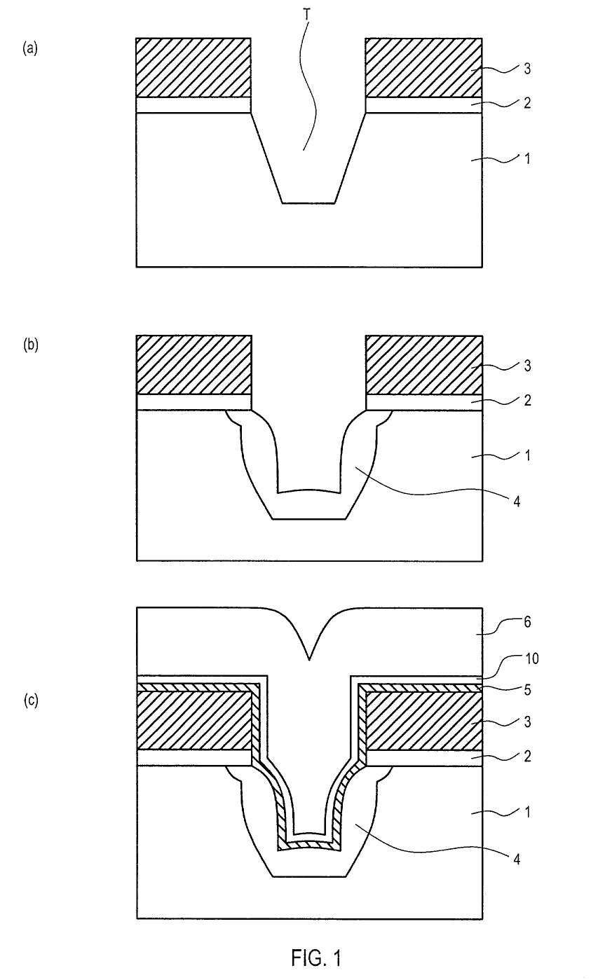

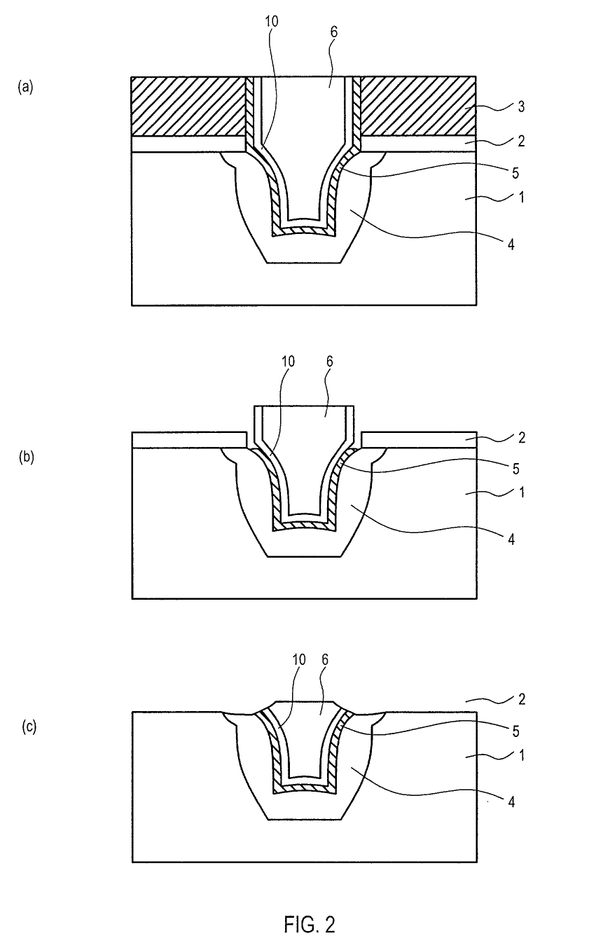

FIGS. 1 and 2 are cross sectional views of a semiconductor device according to an embodiment after various processing steps.

FIGS. 1 and 2 illustrate an example of a method of forming a trench isolation structure (a trench isolation method) in a semiconductor device.

Referring now to FIG. 1(a), a silicon oxide film 2 and a silicon nitride film 3 may be formed sequentially on a silicon substrate 1. Silicon oxide film 2 may have a thickness of about 5 to 30 nm. Silicon nitride film 3 may have a thickness of about 140 to 200 nm. A resist pattern (not shown) may then be formed so as to expose silicon nitride film 3 over a region (a non-active region) where a trench T may be formed. Using the resist pattern as a mask, silicon nitride film 3 and silicon oxide film 2 may be etched sequentially until a surface of silicon substrate 1 is exposed in the non-active region. The resist pattern may then be removed. After the resist pattern is removed, the exposed surface of silicon substrate 1 may be etched using silicon nitride film 3 as a mask. In this way, a trench T may be formed. Trench T may have a depth of about 200 to 500 nm from a substrate plane.

Referring now to FIG. 1(b), a thermal oxide film 4 may then be formed as a first insulating film on an inner wall surface of trench T. Thermal oxide film 4 may have a thickness of about 10 to 20 nm. Thermal oxide film 4 may compensate for damage to the substrate surface caused by etching carried out to form trench T. Thermal oxide film 4 may also prevent dislocations from occurring inside the substrate 1 by rounding off corners of trench T to relieve stress.

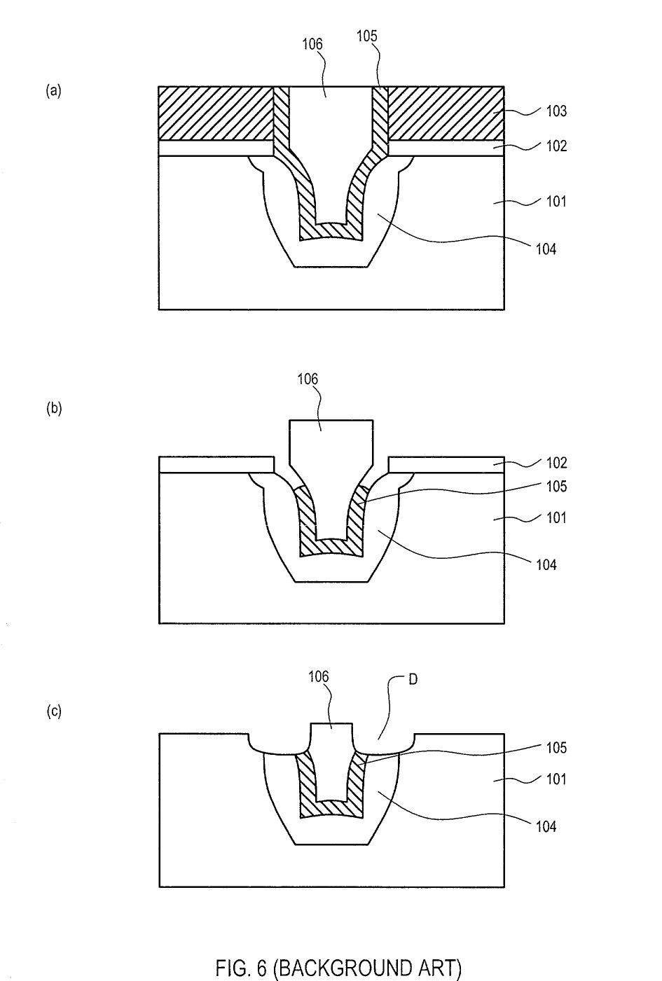

Referring now to FIG. 1(c), a nitride film liner (a silicon nitride film liner) 5 may then be formed as a second oxidation-resistant insulating film over the surface of substrate 1. Nitride film liner 5 may be formed by, for example, a low pressure chemical vapor deposition (LPCVD) method that provides excellent film quality and step coverage. The deposition temperature may be set to about 600 to 800° C. Nitride film liner 5 may have a thickness of preferably 4 nm or more, more preferably at least 5 nm, and may be preferably 20 nm or less, more preferably 10 nm or less, and further preferably 7 nm or less. If nitride film liner 5 is excessively thin, an anti-oxidation effect on a portion inside a trench wall may be rendered insufficient. On the other hand, if nitride film liner 5 is excessively thick, a part of silicon nitride film liner 5 inside trench T may also be etched when silicon nitride film 3 is removed by wet etching (described later with reference to FIGS. 2(a) and 2(b)). If silicon nitride liner 5 inside trench is over-etched in such a manner, a groove D may be formed as illustrated in FIG. 6(c) and discussed in the background. This may cause undesired effects such as a short circuit of gate electrodes, or the like.

Referring still to FIG. 1(c), an anti-static insulating film 10 may be formed on nitride film liner 5. Anti-static insulating film 10 may prevent peeling off of an insulating film embedded inside trench T by a plasma CVD method. The plasma CVD method may be a high-density plasma CVD method. It is preferable to form anti-static film 10 by a CVD method other than a plasma CVD method, i.e. a thermal CVD method, and particularly by a CVD method other than a high-density plasma CVD method. In this way, nitride film liner 5 formed inside the trench may have a reduced electrical charge. Various low pressure CVD methods and atmospheric CVD methods may be used as the thermal CVD method, however, a low pressure CVD method providing excellent film quality and step coverage is preferable.

A variety of oxide films, such as a silicon oxide film, or the like, may be used as anti-static insulating film 10. An HTO (high temperature oxide) oxide film, an LP-TEOS-NSG (low pressure tetra ethyl ortho silicate non-doped silicate glass) oxide film, and the like may also be used as ant-static insulating film 10, to name just a few examples.

Anti-static insulating film 10 may have a thickness of about 5 to 30 nm. If anti-static insulating film 10 is excessively thin, nitride liner 5 and an embedding insulating film 6 (to be formed later) may not be sufficiently prevented from being peeled off. On the other hand, if an anti-static insulating film 10 is excessively thick, embedding or filling properties provided by embedding insulating film 6 (to be formed later) may deteriorate due to the inside of trench T being excessively narrowed.

Referring still to FIG. 1(c), an embedding insulating film 6 may be formed on anti-static insulating film 10. Embedded silicon oxide film 6 may be an embedded silicon oxide film and may have a thickness of about 400 to 600 nm. Embedded silicon oxide film 6 may be a second insulating film formed by a plasma CVD method, as just one example, so as to fill trench T. A plasma CVD method may preferably be a high-density plasma CVD (a bias high-density plasma CVD) method in terms of embeddability or filling of trench T and compactness of the film.

The high-density plasma CVD method may be characterized by high embeddability with respect to a minute concave portion pattern such as illustrated in trench T. The high-density plasma CVD method may employ low-temperature plasma with an ionization density of about 10¹¹ to 10¹²/cm³ that is higher by about two orders of magnitude than in an ordinary plasma CVD. In the high-density plasma CVD method, an inductively coupled plasma (ICP) or electron cyclotron resonance (ECR) type chamber structure may be employed that can produce a lot of plasma, which is different from a parallel-plate type used in an ordinary plasma CVD. A bias may be applied to the substrate in the high-density plasma CVD method, in contrast to the ordinary plasma CVD where the substrate may be maintained at a ground or electrically floating.

Conditions for deposition by the high-density plasma CVD method may be as follows, for example. A silane gas, oxygen gas, and argon gas may be used. The silane gas may have a flow rate set to about 50 to 200 sccm (ml/min (normal)). The oxygen gas may have a flow rate set to about 100 to 350 sccm (ml/min (normal)). The argon gas may have a flow rate set to about 50 to 150 sccm (ml/min (normal)). The deposition temperature may be set in the range of about 300 to 900° C. and it is preferable to set the deposition temperature in a range of about 600 to 800° C. Electric power extracted may be set in the range of up to about 5,000 W and it is preferably in the range of about 2,000 to 5,000 W and further preferably in the range of about 3,000 to 4,000 W.

A baking compaction treatment may be carried out for the purpose of increasing compactness of an embedded insulating film 6. This may make it more difficult for embedding insulating film 6 filling the inside of trench T to be etched in a later wet washing step. Examples of the baking compaction treatment include an oxidation treatment at about 800° C. or higher and an annealing treatment at about 1,000° C. or higher in a nitrogen atmosphere.

Referring now to FIG. 2(a), etch back may be carried out by chemical mechanical polishing (CMP) or dry etching until silicon nitride film 3 is exposed. In this way, the surface of the semiconductor device may be flattened.

Referring now to FIG. 2(b), silicon nitride film 3 over the active region may be removed by wet etching with a phosphoric acid solution, or the like. At this time, a part of nitride film liner 5 inside the trench may also be removed. However, because nitride film liner 5 is formed to have a thin film thickness, the etching amount of nitride film liner 5 inside the trench may be suppressed in the wet etching step.

Referring now to FIG. 2(c), silicon oxide film 2 over an active region and a protruding portion formed of embedding insulating film 6 and anti-static insulating film 10 in a non-active region may be removed by wet etching or the like. Because etching of a part of nitride film liner 5 has been suppressed in an etching step illustrated in FIG. 2(b), a size of a groove D formed along an edge of a trench isolation region may be suppressed to some degree. In this way, a failure such as a short circuit or the like in a step of forming gate electrodes may be suppressed. Furthermore, device characteristics, such as a device threshold voltage or the like may not be affected due to an increased electric field in the region and leakage current may be suppressed.

According to the above-mentioned method, a lift due to peeling of or delaminating of embedded insulating film 6 did not occur in a trench isolation structure with the trench depth of 350 nm from the substrate surface, inside of which a nitride film liner 5 and anti-static film 10 are formed in thicknesses of about 6 nm and 20 nm each, and the embedding insulating film 6 are formed by a high-density plasma CVD method.

The high-density plasma CVD deposition conditions include:

CVD device: Centura, manufactured by Applied Material Japan Inc.;

Deposition temperature: 730° C.;

Electric power extracted: 3500 W;

Gas conditions: a SiH₄ gas flow rate of 120 sccm (ml/min (normal)), an O₂ gas flow rate of 260 sccm (ml/min (normal)), and an Ar gas flow rate of 90 sccm (ml/min (normal));

DS (deposition / sputter rate): 4.6.

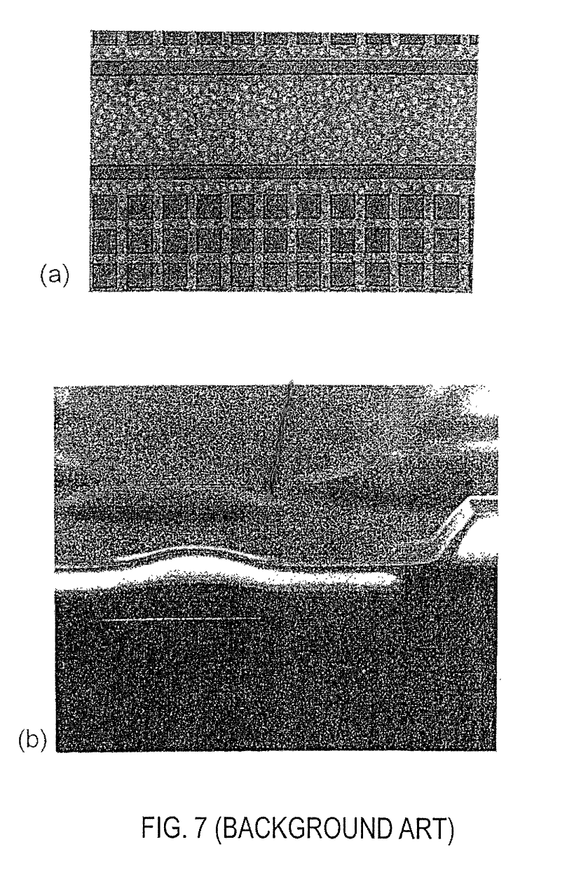

As a comparison to the above-mentioned example, a trench isolation structure was formed in the same manner as that in the above-mentioned example except that anti-static insulating film (silicon oxide film) 10 was not formed. In this case, the peeling off of the embedding insulating film was observed as shown in the photographs of FIGS. 7(a) and 7(b).

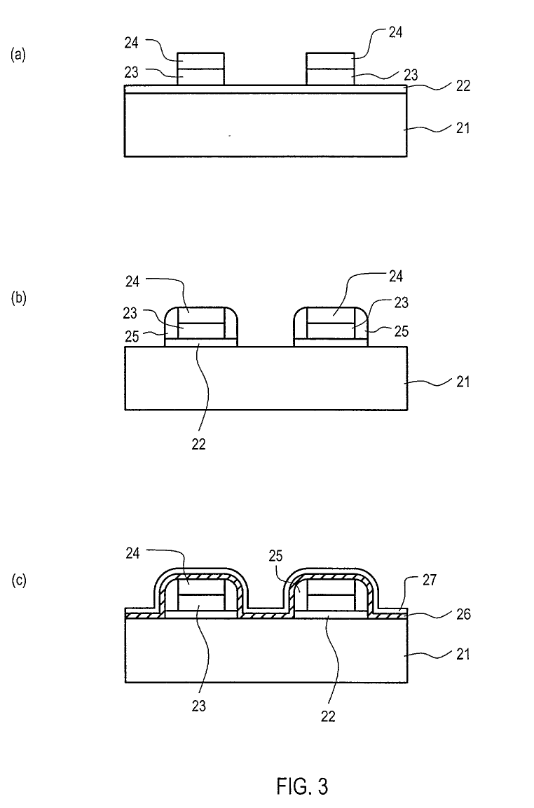

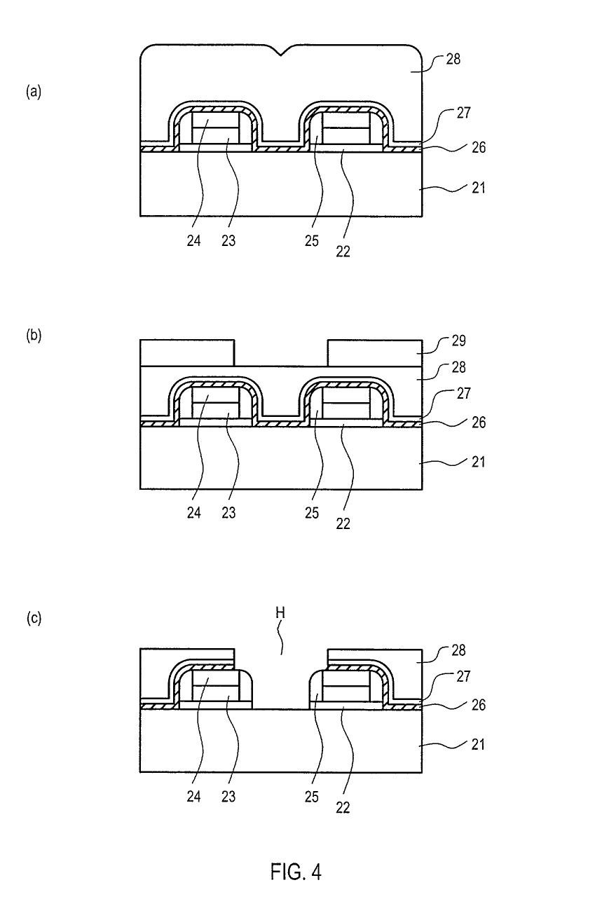

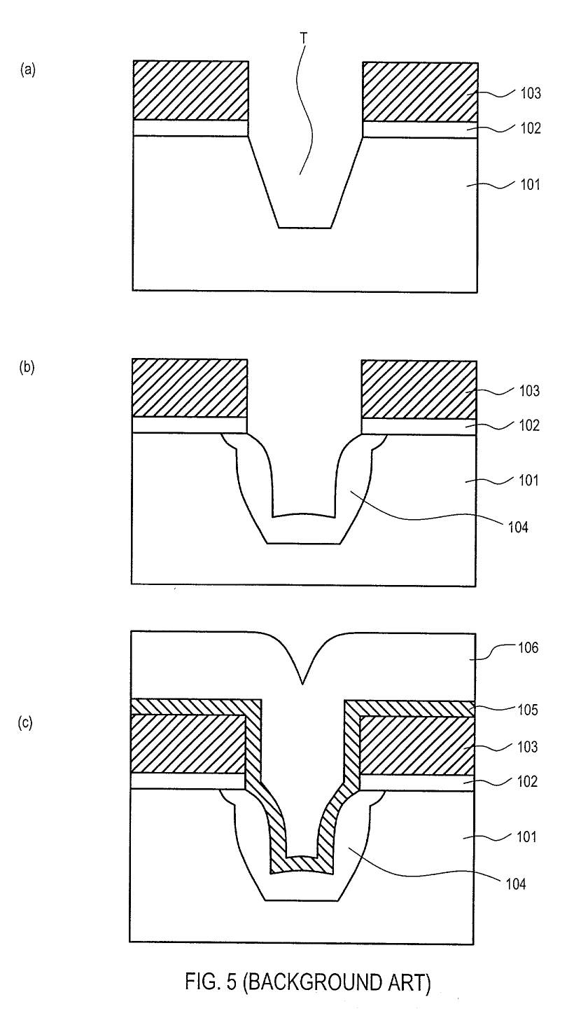

In addition to the trench isolation structure as described with reference to FIGS. 1 and 2, the present invention may be applied to a formation of an interlayer insulating film formed to fill a concave portion (gap) between minutely constructed gate electrodes via a nitride film. Specifically, the present invention may be suitable for the formation of an interlayer insulating film in a self-aligning contact structure formed between minutely constructed gate electrodes. A description of such an embodiment will now be set forth with reference to FIGS. 3 and 4.

FIGS. 3 and 4 are cross sectional views of a semiconductor device according to an embodiment after various processing steps.

Referring now to FIG. 3(a), a gate oxide film 22 may be formed on a silicon substrate 21. Next, an electrically conductive film, such as an impurity-introduced polysilicon film or the like, and a silicon nitride film may be formed thereon. Subsequently, the silicon nitride film and the electrically conductive film may be patterned and etched to respectively form capping layers 24 and gate electrodes 23.

Referring now to FIG. 3(b), an insulating film such as a silicon nitride film, a silicon oxide film, or the like may be formed over the whole substrate surface and then etched back by anisotropic etching. In this way, side walls 25 may be formed on side surfaces of gate electrodes 23 and capping layers 24. At this time, gate oxide film 22 on the substrate in regions between side walls 25 on side surfaces of gate electrodes 23 may be removed or made thinner.

Next, an oxide film (not shown) may be formed on the substrate between side walls 25 on side surfaces of gate electrodes 23. Ion implantation may then be carried out through this oxide film to form a source/drain region (not shown). For example, a source/drain region may be formed in substrate 21 between gate electrodes 23. Such a source/drain region may be a common source/drain region of minutely formed adjacent gate electrodes 23. The substrate surface may then be subjected to wet washing by a usual method. In the wet washing, the oxide film on the substrate between the side walls 25 on the side surfaces of gate electrodes 23 may be removed or made thinner.

Referring now to FIG. 3(c), an etching stopper film 26 may be formed over the whole substrate surface, which prevent etching of the substrate or silicon oxide on the trench isolation in the later contact dry etching process. Etching stopper film 26 may be oxidation—resistant insulator such as a silicon nitride film, as just one example. Etching stopper film 26 may have a preferable thickness of about 4 nm to 20 nm. If etching stopper film 26 is excessively thin, the etching stopper function may not be sufficient. If etching stopper film 26 is excessively thick, a space between gate electrodes 23 may become overly narrow and a width of a contact region may not be sufficient.

Referring still to FIG. 3(c), an anti-static insulating film 27 may be formed on etching stopper film 26. Anti-static insulating film 27 may be formed in essentially the same manner as anti-static insulating film 10 illustrated in FIG. 1(c). The formation of anti-static insulating film 27 may prevent peeling off or delaminating of an interlayer insulating film to be formed by a plasma CVD method (a high-density plasma CVD method) to fill a portion between gate electrodes. It is preferable to form this anti-static insulating film 27 by a CVD method other than the plasma CVD method, i.e. a thermal CVD method, and particularly by a CVD method other than a high-density plasma CVD method. In this way, etching stopper film 26 may have electric charge suppressed. Various low pressure CVD methods and atmospheric CVD methods may be used as a thermal CVD method, but among them, a low pressure CVD method providing excellent film quality and step coverage is preferable.

A variety of oxide films such as a silicon oxide film or the like may be used as anti-static insulating film 27. Also, an HTO oxide film, an LP-TEOS-NSG oxide film, and the like, may be used.

Anti-static insulating film 27 may preferably have a thickness of about 5 nm to 30 nm. If anti-static insulating film 27 is excessively thin, etching stopper film 27 and an interlayer insulating film (FIG. 4(a)) 28 to be formed later may not be sufficiently prevented from being peeled off or delaminating. On the other hand, if anti-static insulating film 27 is excessively thick, embeddability or filling properties provided by interlayer insulating film 28 may not be sufficient because a concave portion (gap) between gate electrodes 23 may be narrowed.

Referring now to FIG. 4(a), an interlayer insulating film 28 may be formed over the surface. Interlayer insulating film 28 may be formed by a plasma CVD method, preferably by a high-density plasma CVD method, so as to fill a concave portion (gap) between gate electrodes 23. Interlayer insulating film 28 may be formed through sequential lamination of an insulating film formed to fill a concave portion between the gate electrodes by a plasma CVD method or a high-density plasma CVD method and another insulating film formed thereon by another thermal CVD method such as a low pressure CVD method or the like.

Referring now to FIG. 4(b), interlayer insulating film 28 may be subjected to a flattening treatment to obtain a predetermined thickness by a CMP method, etch back, or the like. A resist pattern 29 for contact hole formation may then be formed.

Referring now to FIG. 4(c), using resist pattern 29 as a mask, etching may be carried out to form an opening to expose at least etching stopper film 26 on the substrate between adjacent gate electrodes 23. Exposed etching stopper film 26 may then be removed by etching to expose a surface of substrate 21 between adjacent gate electrodes 23. In this way, a contact hole H may be formed in a self-aligning manner.

Contact hole H may then be filled with an electrically conductive material by a usual method to form a contact plug (not shown) that may electrically connect an upper layer wiring or the like with the source/drain region. In this way, a self-aligning contact structure may be obtained.

In accordance with the present embodiments, an embedding insulating film may be formed inside a concave portion of a substrate covered with an oxidation-resistant insulating film via an anti-static insulating film. The embedding insulating film may be formed by a plasma CVD method or a high-density plasma CVD method that has excellent embeddability or filling properties. In this way, a peeling off or delaminating that may occur due to charged particles during deposition may be prevented. Because a deposition method having excellent embeddability or filling properties may be used, a concave portion of minute construction covered with a thin oxidation-resistant insulating film may be sufficiently filled.

It is understood that the embodiments described above are exemplary and the present invention should not be limited to those embodiments. Specific structures should not be limited to the described embodiments.

Thus, while the various particular embodiments set forth herein have been described in detail, the present invention could be subject to various changes, substitutions, and alterations without departing from the spirit and scope of the invention. Accordingly, the present invention is intended to be limited only as defined by the appended claims.

What is claimed is:

1. A semiconductor device, comprising:
a plurality of first concave portions formed on a semiconductor substrate, each concave portion including an oxidation resistant insulating film formed thereon and an anti-static insulating film formed on the oxidation resistant insulating film; and
an embedding insulating film formed inside each of the concave portions to essentially fill each of the concave portions.

2. The semiconductor device according to claim 1, wherein:
each concave portion is a trench isolation region including a first insulating film formed on trench walls.

3. The semiconductor device according to claim 1, wherein:
each concave portion is essentially defined by adjacent gate electrodes.

4. The semiconductor device according to claim 1, wherein:
formation of the anti-static insulating film includes thermal chemical vapor deposition (CVD).

5. The semiconductor device according to claim 1, wherein:
formation of the anti-static insulating film includes plasma CVD.

6. The semiconductor device according to claim 1, wherein:
formation of the anti-static insulating film includes high-density plasma CVD.

7. The semiconductor device according to claim 1, wherein:
the oxidation-resistant insulating film includes a nitride film with a thickness of about 4 nm to 20 nm.

8. The semiconductor device according to claim 1, wherein:
the anti-static insulating film includes an oxide film with a thickness of about 5 nm to 30 nm.

9. A method of manufacturing a semiconductor device, comprising the steps of:
forming an oxidation-resistant insulating film on a surface including a concave portion formed on a semiconductor substrate;
forming an anti-static insulating film on the oxidation-resistant insulating film; and
forming an embedding insulating film on the anti-static insulating film to essentially fill the concave portion wherein the formation of the embedding insulating film includes plasma chemical vapor deposition (CVD).

10. The method of manufacturing the semiconductor device according to claim 9, wherein:
the concave portion is essentially defined by adjacent gate electrodes.

11. The method of manufacturing the semiconductor device according to claim 10, wherein:
forming the embedding insulating film includes high-density plasma chemical vapor deposition (CVD).

12. The method of manufacturing the semiconductor device according to claim 11, wherein:
the oxidation-resistant insulating film includes a nitride film having a thickness of about 4 nm to 20 nm.

13. The method of manufacturing the semiconductor device according to claim 11, wherein:
forming the anti-static insulating film includes a thermal CVD method.

14. The method of manufacturing the semiconductor device according to claim 11, wherein:
the anti-static insulating film includes an oxide film having a thickness of about 5 nm to 30 nm.

15. A method of manufacturing a semiconductor device, comprising the steps of:
forming a mask layer including a first oxidation-resistant insulating film on a semiconductor substrate;
forming a predetermined opening pattern in the mask layer;
forming a trench by etching an exposed portion of the semiconductor substrate with the mask layer used as a mask;
forming a first insulating film on an inner wall of the trench;
forming a second oxidation-resistant insulating film on the first insulating film;
forming an anti-static insulting film on the second oxidation-resistant insulating film;
forming a second insulating film on the anti-static insulating film by a plasma chemical vapor deposition (CVD) method to essentially fill the trench;
carrying out a flattening treatment so that the mask layer is exposed; and
removing the mask layer by wet etching
wherein a trench isolation structure is formed including the second insulating film, the first insulating film, the second oxidation-resistant film, and the anti-static insulating film.

16. The method of manufacturing the semiconductor device according to claim 15, wherein:
forming the second insulating film includes high-density plasma CVD.

17. The method of manufacturing the semiconductor device according to claim 15, wherein:
the second oxidation-resistant insulating film includes a nitride film having a thickness of about 4 nm to 20 nm.

18. The method of manufacturing the semiconductor device according to claim 15, wherein:
the second oxidation-resistant insulating film includes a nitride film having a thickness of about 5 nm to 7 nm.

19. The method of manufacturing the semiconductor device according to claim 15, wherein:
forming the anti-static insulating film includes a thermal CVD method.

20. The method of manufacturing the semiconductor device according to claim 15, wherein:
the anti-static insulating film includes an oxide film having a thickness of about 5 nm to 30 nm.
